(19) United States
(12) Patent Application Publication
(10) Pub. No.: US 2009/0206740 A1
(43) Pub. Date: Aug. 20, 2009

(54) ORGANIC LIGHT EMITTING DIODE AND METHOD OF FABRICATING THE SAME

(75) Inventors: Min-Seung Chun, Suwon-si (KR); Mi-Kyung Kim, Suwon-si (KR); Dong-Heon Kim, Suwon-si (KR); Jae-Hyun Kwak, Suwon-si (KR); Jung-Ha Son, Suwon-si (KR); Kwan-Hee Lee, Suwon-si (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Suwon-si (KR)

(21) Appl. No.: 12/359,574

(22) Filed: Jan. 26, 2009

(30) Foreign Application Priority Data
Jan. 28, 2008 (KR) 2008-8721

(51) Int. Cl. H01J 1/63; H01L 21/28

(52) U.S. Cl. 313/504; 438/29; 257/E21.158; 257/40

(57) ABSTRACT

An organic light emitting diode includes a first electrode, an organic layer disposed on the first electrode and including an emission layer and an electron transport layer, and a second electrode disposed on the organic layer. The electron transport layer includes an organic metal complex including beryllium and one of compounds of formula 1:

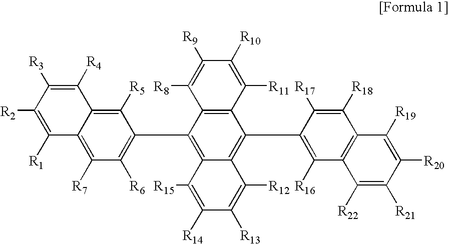

wherein R₁ to R₂₂ are as defined in the specification.

### CROSS-REFERENCE TO RELATED APPLICATIONS

This application claims the benefit of Korean Patent Application No. 2008-8721, filed Jan. 28, 2008, the disclosure of which is hereby incorporated herein by reference.

### BACKGROUND OF THE INVENTION

1. Field of the Invention

Aspects of the present invention relates to an organic light emitting diode (OLED) and a method of fabricating the same. More particularly, aspects of the present invention relate to an OLED that can improve driving voltage, current consumption, emission efficiency and life span characteristics by forming an improved electron transport layer, and a method of fabricating the same.

2. Description of the Related Art

Organic light emitting diodes (OLEDs) are self emissive displays that are thin and light, and can have a simple structure fabricated in a simple process, display a high quality picture with a wide viewing angle, implement a perfect motion picture and high color purity, and have electrical characteristics of low power consumption and low driving voltage, which are suitable for mobile displays.

Generally, the OLED includes a pixel electrode, an organic layer having an emission layer disposed on the pixel electrode, and a counter electrode disposed on the organic layer.

In addition, to effectively inject holes and electrons into the emission layer from the pixel electrode and the counter electrode, the organic layer may further include at least one selected from the group consisting of a hole injection layer, a hole transport layer and an electrode blocking layer between the pixel electrode and the emission layer, and at least one selected from the group consisting of a hole blocking layer, an electron transfer layer and an electron injection layer between the emission layer and the counter electrode.

However, an electron transport layer of the organic layer is typically formed of a single organic material, and an OLED display device that includes such an electron transport layer may have poor driving voltage, current consumption, emission efficiency and life span characteristics, and thus may not implement high quality display.

### SUMMARY OF THE INVENTION

Aspects of the present invention provide an organic light emitting diode that has an improved electron transport layer, thereby improving driving voltage, current consumption, emission efficiency and life span characteristics, and a method of fabricating the same.

According to an embodiment of the present invention, an organic light emitting diode includes: a first electrode, an organic layer disposed on the first electrode and including an emission layer and an electron transport layer, and a second electrode disposed on the organic layer. The electron transport layer includes an organic metal complex including beryllium and a compound of Formula 1.

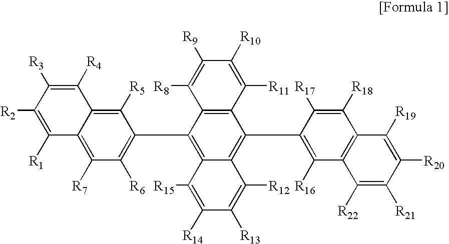

In the compound of Formula 1, R₁ to R₇, and R₁₆ to R₂₂ are independently selected from the group consisting of hydrogen, phenyl, indenyl, naphthalenyl, benzofuranyl, benzothiophenyl, indolyl, benzimidazolyl, benzothiazolyl, purinyl, quinolinyl, isoquinolinyl, coumarinyl, cinnolinyl, quinoxalinyl, azulenyl, fluorenyl, dibenzofuranyl, carbazolyl, anthracenyl, phenanthrenyl, aziridinyl, 1,10-phenanthrolinyl, phenothiazinyl and pyrenyl groups.

Regarding R₈ to R₁₅, according to one alternative, at least one of R₈ to R₁₅ is a C3-C30 aromatic heterocyclic group that includes one ring with two nitrogen atoms, and the other ones of R₈ to R₁₅ are independently selected from the group consisting of hydrogen, phenyl, indenyl, naphthalenyl, benzofuranyl, benzothiophenyl, indolyl, benzothiazolyl, quinolinyl, isoquinolinyl, coumarinyl, azulenyl, fluorenyl, dibenzofuranyl, carbazolyl, anthracenyl, phenanthrenyl, aziridinyl, phenothiazinyl, and pyrenyl groups. A compound in which R₁ to R₈, R₁₁ and R₁₂, and R₁₅ to R₂₂ are hydrogen, and one of R₉, R₁₀, R₁₃ and R₁₄ is the C3 to C30 aromatic heterocyclic group having one ring with two nitrogen atoms is specifically excluded.

According to another alternative, one of R₈ to R₁₅ is a phenyl group coupled with a C3-C30 aromatic heterocyclic group that includes one ring with two nitrogen atoms, and the other ones of R₈ to R₁₅ are independently selected from the group consisting of hydrogen, phenyl, indenyl, naphthalenyl, benzofuranyl, benzothiophenyl, indolyl, benzothiazolyl, quinolinyl, isoquinolinyl, coumarinyl, azulenyl, fluoreinyl, dibenzofuranyl, carbazolyl, anthracenyl, phenanthrenyl, aziridinyl, phenothiazinyl, and pyrenyl groups.

According to another embodiment of the present invention, a method of fabricating an organic light emitting diode includes: preparing a first electrode; forming an organic layer including an emission layer and an electron transport layer on the first electrode; and forming a second electrode on the organic layer. Here, wherein the electron transport layer is formed by co-depositing an organic metal complex including beryllium and a compound of Formula 1 according to the alternatives defined above.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a cross-sectional view of an organic light emitting diode (OLED) according to an embodiment of the present invention; and

FIG. 2 is a life span graph according to Experimental example 1 and Comparative example 1.

### DETAILED DESCRIPTION OF THE EMBODIMENTS

Reference will now be made in detail to the present embodiments of the present invention, examples of which are shown in the accompanying drawings, wherein like reference numerals refer to the like elements throughout the specification. The embodiments are described below in order to explain the present invention by referring to the figures. It is to be understood that where is stated herein that one layer is “formed on” or “disposed on” a second layer, the first layer may be formed or disposed directly on the second layer or there may be intervening layers between the first layer and the second layer. Further, as used herein, the term “formed on” is used with the same meaning as “located on” or “disposed on” and is not meant to be limiting regarding any particular fabrication process.

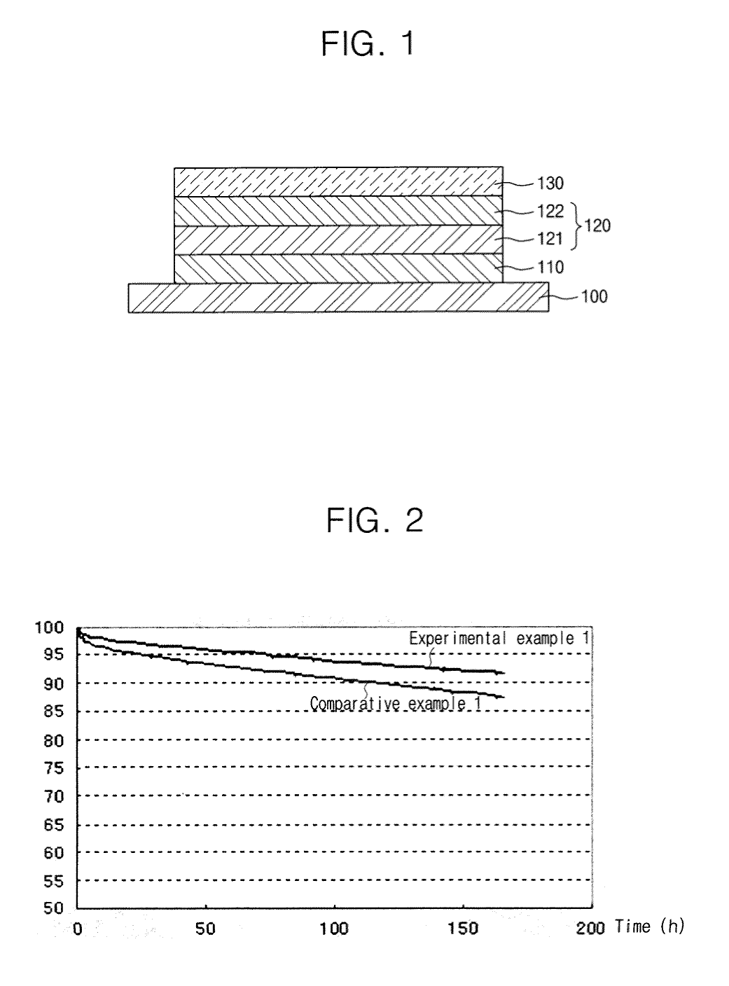

FIG. 1 is a cross-sectional view of an organic light emitting diode (OLED) according to an embodiment of the present invention.

First, referring to FIG. 1, a substrate 100 is provided. The substrate 100 may be formed of any suitable material such as, for example, glass, plastic or stainless steel. The substrate 100 may include at least one thin film transistor (not illustrated) connected to a first electrode.

A first electrode 110 is disposed on the substrate 100. The first electrode 110 may be an anode, and a transparent or reflective electrode. When the first electrode 110 is a transparent electrode, the first electrode 110 may be formed of indium tin oxide (ITO), indium zinc oxide (IZO), tin oxide (TO) or zinc oxide (ZnO). Or, when the first electrode 110 is a reflective electrode, the first electrode 110 may have a stacked structure of a reflective layer formed of silver (Ag), aluminum (Al), chromium (Cr), molybdenum (Mo), tungsten (W), titanium (Ti), gold (Au), palladium (Pd) or an alloy thereof, and a transparent layer formed of ITO, IZO, TO or ZnO on the reflective layer. The first electrode 110 may be formed by any suitable method such as, for example, sputtering, vapor phase deposition, ion beam deposition, electron beam deposition or laser ablation.

Then, an organic layer 120 including an emission layer 121 and an electron transport layer 122 is disposed on the first electrode 110.

The emission layer 121 may be a phosphorescent or fluorescent emission layer. if the emission layer is a fluorescent emission layer, the emission layer may include a material selected from the group consisting of 8-trishydroxyquinoline aluminum (Alq3), distyrylarylene (DSA), distyrylarylene derivatives, distyrylbenzene (DSB), distyrylbenzene derivatives, 4,4′-bis(2,2′-diphenyl vinyl)-1,1′-biphenyl (DPVBi), DPVBi derivatives, spiro-DPVBi, spiro-sexyphenyl (spiro-6P), and 9,10-bis(2-naphthyl)anthracene. The emission layer 121 may further include a dopant material selected from the group consisting of styrylamines, perylenes and distyrylbiphenyls (DSBPs).

Alternatively, if the emission layer is a phosphorescent emission layer, the emission layer may include one selected from the group consisting of arylamines, carbazoles and spiro compounds as a host material. As non-limiting examples, the host material may be one selected from the group consisting of 4,4-N,N-dicarbazole-biphenyl (CBP), CBP derivatives, N,N-dicarbazolyl-3,5-benzene (mCP), mCP derivatives and spiro derivatives. The emission layer 121 may further include a phosphorescent organic metal complex with one central metal selected from the group consisting of iridium (Ir), Pt, terbium (Tb) and europium (Eu) as a dopant material. Furthermore, the phosphorescent metal complex may be one selected from the group consisting of PQIr, PQIr (acac), PQ₂Ir(acac), PIQIr (acac), Ir(piq)₃, Ir(ppy)₃ and PtOEP.

An electron transport layer 122 is disposed on the emission layer 121. The electron transport layer 122 according to aspects of the present invention includes an organic metal complex having beryllium and a compound of Formula 1:

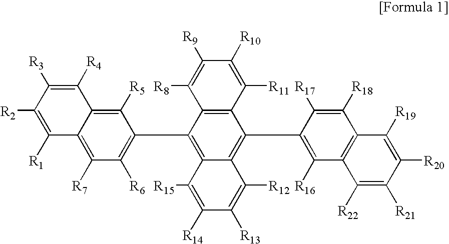

In Formula 1, R₁ to R₇, and R₁₆ to R₂₂ are independently selected from the group consisting of hydrogen, phenyl, indenyl, naphthalenyl, benzofuranyl, benzothiophenyl, indolyl, benzimidazolyl, benzothiazolyl, purinyl, quinolinyl, isoquinolinyl, coumarinyl, cinnolinyl, quinoxalinyl, azulenyl, fluorenyl, dibenzofuranyl, carbazolyl, anthracenyl, phenanthrenyl, aziridinyl, 1,10-phenanthrolinyl, phenothiazinyl and pyrenyl groups.

Regarding R₈ to R₁₅, according to one alternative, at least one of R₈ to R₁₅ is a C3-C30 aromatic heterocyclic group having one ring that includes two nitrogen atoms, and the other ones of R₈ to R₁₅ are independently selected from the group consisting of hydrogen, phenyl, indenyl, naphthalenyl, benzofuranyl, benzothiophenyl, indolyl, benzothiazolyl, quinolinyl, isoquinolinyl, coumarinyl, azulenyl, fluorenyl, dibenzofuranyl, carbazolyl, anthracenyl, phenanthrenyl, aziridinyl, phenothiazinyl, and pyrenyl groups. Further, a compound in which R₁ to R₈, R₁₁ and R₁₂, and R₁₅ to R₂₂ are hydrogen, and one of R₉, R₁₀, R₁₃ and R₁₄ is the C3 to C30 aromatic heterocyclic group having one ring with two nitrogen atoms is specifically excluded.

According to another alternative, one of R₈ to R₁₅ is a phenyl group that is coupled with a C3-C30 aromatic heterocyclic group having one ring that includes two nitrogen atoms, and the other ones of R₈ to R₁₅ are independently selected from the group consisting of hydrogen, phenyl, indenyl, naphthalenyl, benzofuranyl, benzothiophenyl, indolyl, benzothiazolyl, quinolinyl, isoquinolinyl, coumarinyl, azulenyl, fluorenyl, dibenzofuranyl, carbazolyl, anthracenyl, phenanthrenyl, aziridinyl, phenothiazinyl, and pyrenyl groups.

Specifically, the C3 to C30 aromatic heterocyclic group having one ring that includes two nitrogen atoms may be selected from the group consisting of imidazolyl, benzimidazolyl, pyrazolyl, pyrazolinyl, pyrazolidinyl, oxadiazolyl, thiadiazolyl, pyridazinyl, pyrimidinyl, piperazinyl, purinyl, cinnolinyl, quinoxalinyl, and phenanthrenyl groups.

As a non-limiting example, the organic metal complex having beryllium may be bis(10-hydroxybenzo[h]quinolinato)beryllium (BeBq₂).

The organic metal complex having beryllium may be included in the electron transport layer 122 at a concentration of 10 to 60 wt %. Due to the high electron affinity of beryllium, the organic metal complex having beryllium can sufficiently interact with lone electron pairs present in the two nitrogen atoms in the aromatic heterocyclic group located in at least one of R₈ to R₁₅ of the compound of Formula 1, or lone electron pairs present in the two nitrogen atoms in the aromatic heterocyclic group coupled to the phenyl group that is one of R₈ to R₁₅ of the compound of Formula 1, thereby significantly improving efficiencies of electron transport and injection to the emission layer 121.

The electron transport layer 122 may be formed by co-depositing the organic metal complex having beryllium and a compound of Formula 1.

Since the electron transport layer 122 is formed by interaction between the organic metal complex having beryllium with high electron affinity and the lone electron pairs present in the two nitrogen atoms in the C3-C30 aromatic heterocyclic group having one ring that includes two nitrogen atoms included in the compound of Formula 1, compared to a conventional electron transport layer formed of only a single organic material, the efficiencies of electron transport and injection to the emission layer 121 can be significantly improved, and thus driving voltage, current consumption, emission efficiency and life span characteristics of the organic light emitting diode (OLED) can be improved. The electron transport layer 122 also has an electron injection characteristic, so that a separate electron injection layer is not needed, which can make a fabrication process simple.

The organic layer 120 may further include at least one selected from the group consisting of a hole injection layer, a hole transport layer, an electron blocking layer, a hole blocking layer and an electron injection layer to increase injection of electrons and holes into the emission layer 121 and recombination between the electrons and the holes in the emission layer 121.

The hole injection layer serves to facilitate the hole injection into the emission layer 121 and increase the life span of the device. As non-limiting examples, the hole injection layer may be formed of arylamine-based compounds or starburst amines. TAs more specific, non-limiting examples, the hole injection layer may be formed of 4,4,4-tris(3-methylphenylamino)triphenylamino (m-MTDATA), 1,3,5-tris[4-(3-methylphenylamino)phenyl]benzene (m-MTDATB) or copper phthalocyanine (CuPc).

As non-limiting examples, the hole transport layer may be formed of arylene diamine derivatives, starburst compounds, biphenyldiamine derivatives having a spiro group, or trapezoidal compounds. As more specific, non-limiting examples, the hole transport layer may be formed of N,N-diphenyl-N,N-bis(4-meythylphenyl)-1,1-biphenyl-4,4,-diamine (TPD) or 4,4-bis[N-(1-naphthyl)-N-phenylamino]biphenyl (NPB).

The electron blocking layer serves to inhibit diffusion of excitons generated in the emission layer 121 during a driving procedure of the OLED. As non-limiting examples, the electron blocking layer may be formed of bis(2-methyl-8-quinolinolato-N1,O8)-(1,1′-biphenyl-4-olato)aluminum (BAlq), bathocuproine (BCP), a polymerized fluorocarbon (CF-X), 3-(4-t-butylphenyl)-4-phenyl-5-(4-biphenyl)-1,2,4-triazole (TAZ) or spiro-TAZ.

The hole blocking layer serves to prevent move of holes to the electron injection layer when hole mobility is higher than electron mobility in an organic emission layer. As non-limiting examples, the hole blocking layer may be formed of one selected from the group consisting of 2-(4-biphenyl)-5-(4-tert-butylphenyl)-1,3,4-oxydiazole (PBD), spiro-PBD and 3-(4-t-butylphenyl)-4-phenyl-5-(4-biphenyl)-1,2,4-triazole (TAZ).

As non-limiting examples, the electron injection layer may be formed of at least one selected from the group consisting of 1,3,4-oxydiazole derivatives, 1,2,4-triazole derivatives and LiF.

The organic layer 120 may be formed by any suitable method such as, for example, vacuum deposition, inkjet printing or laser induced thermal imaging.

Then, a second electrode 130 is disposed on the electron transport layer 122. The second electrode 130 may be a cathode, and a transparent or reflective electrode. When the second electrode 130 is a transparent electrode, the second electrode 130 may be formed as thin as possible using one selected from the group consisting of Mg, Ca, Al, Ag and alloys thereof having a low work function, such that light can penetrate, or when the second electrode 130 is a reflective electrode, the second electrode 130 may be formed as thick as possible to reflect light.

Hereinafter, experimental examples will be provided to help understanding of aspects of the present invention. However, the examples are only provided to help understanding of, and not to limit, the present invention.

### Experimental Example 1

A first electrode was formed to a thickness of 130 nm using ITO. Then, a hole injection layer was formed to a thickness of 130 nm using IDE-406 (Idemitsu) on the first electrode, and a hole transport layer was formed to a thickness of 20 nm using NPB. A blue emission layer was formed to a thickness of 20 nm using a mixture of 9,10-bis(2-naphthyl)anthracene as a host, and 7 wt % BD246 (Idemitsu) as a dopant on the hole transport layer. An electron transport layer was formed to a thickness of 30 nm on the blue emission layer by co-depositing BeBq2, which is an organic metal complex having beryllium, and a compound of Formula 1 in which R₉ is a phenyl group and the remaining substituents are hydrogen atoms, and the phenyl group is coupled with a benzimidazolyl group. The BeBq2 and the compound of Formula 1 were co-deposited at a ratio of 50:50 (wt %). Then, a second electrode was formed by stacking a 16 nm-thick layer of MgAg on the electron transport layer, and a 100 nm-thick layer of Al on the MgAg layer.

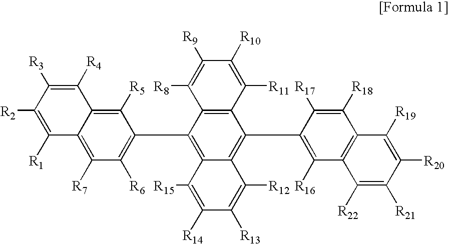

### Comparative Example 1

In Comparative example 1, an electron transport layer was formed to a thickness of 30 nm using only the compound of Formula 1 described in Experimental example 1 and not including BeBq2.

Driving voltages and emission efficiencies of OLEDs fabricated according to Experimental example 1 and Comparative example 1 were measured, and the results are listed in Table 1.

TABLE 1

| | Driving | Emission |
|---|---|---|
| | Voltage | Efficiency |
| | (V) | (cd/A) |
| Experimental example 1 | 4.7 | 4.0 |
| Comparative example 1 | 5.3 | 3.0 |

Referring to Table 1, under the same brightness conditions, in the OLED using the electron transport layer formed of a mixture of the compound of Formula 1 in which R₉ is a phenyl group and the remaining substituents are hydrogen atoms, and the phenyl group is coupled with a benzimidazolyl group, and BeBq₂, as in Experimental example 1, the driving voltage was decreased by about 0.6V (about 11%), and the emission efficiency was increased by 1 Cd/A (about 33%), compared to OLED using the electron transport layer formed of only the organic compound of Formula 1.

Moreover, FIG. 2 is a life span graph for Experimental example 1 and Comparative example 1. In FIG. 2, a horizontal axis is time (h), a vertical axis is the relative rate (%) obtained when initial brightness is set to 100 in Experimental example 1 and Comparative example 1. Referring to FIG. 2, the brightness of the OLED of Experimental example 1 decreased more slowly according to the passage of time than the OLED of Comparative example 1, and thus the life span characteristic was increased in Experimental example 1.

As described above, an OLED display device includes an electron transport layer formed by co-depositing an organic metal complex having beryllium and a compound of Formula 1, so that the OLED display device can have improved driving voltage, current consumption, emission efficiency and life span characteristics. Also, since the electron transport layer has an electron injection characteristic, an OLED does not need a separate electron injection layer, which can make a fabrication process simpler.

Aspects of the present invention provide an OLED that uses an electron transport layer formed of an organic metal complex having beryllium and a compound of Formula 1, thereby improving the driving voltage, current consumption, emission efficiency and life span characteristics, and thus implementing a high quality display. Further, the electron transport layer has an electron injection characteristic, so that a separate electron injection layer is not needed, which can simplify the fabrication process.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An organic light emitting diode (OLED), comprising:
a first electrode;
an organic layer disposed on the first electrode, and including an emission layer and an electron transport layer; and
a second electrode disposed on the organic layer,
wherein the electron transport layer includes an organic metal complex including beryllium and a compound of Formula 1: 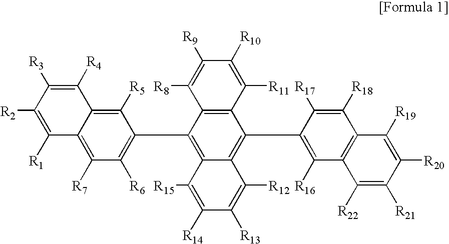
wherein, R₁ to R₇, and R₁₆ to R₂₂ are independently selected from the group consisting of hydrogen, phenyl, indenyl, naphthalenyl, benzofuranyl, benzothiophenyl, indolyl, benzimidazolyl, benzothiazolyl, purinyl, quinolinyl, isoquinolinyl, coumarinyl, cinnolinyl, quinoxalinyl, azulenyl, fluorenyl, dibenzofuranyl, carbazolyl, anthracenyl, phenanthrenyl, aziridinyl, 1,10-phenanthrolinyl, phenothiazinyl and pyrenyl groups, and
at least one of R₈ to R₁₅ is a C3-C30 aromatic heterocyclic group having one ring that includes two nitrogen atoms, and the other ones of R₈ to R₁₅ are independently selected from the group consisting of hydrogen, phenyl, indenyl, naphthalenyl, benzofuranyl, benzothiophenyl, indolyl, benzothiazolyl, quinolinyl, isoquinolinyl, coumarinyl, azulenyl, fluorenyl, dibenzofuranyl, carbazolyl, anthracenyl, phenanthrenyl, aziridinyl, phenothiazinyl, and pyrenyl groups with the proviso that a compound in which R₁ to R₈, R₁, and R₁₂, and R₁₅ to R₂₂ are hydrogen, and one of R₉, R₁₀, R₁₃ and R₁₄ is the C3 to C30 aromatic heterocyclic group having one ring that includes two nitrogen atoms is specifically excluded.

2. The OLED according to claim 1, wherein the C3 to C30 aromatic heterocyclic group having one ring that includes two nitrogen atoms is one selected from the group consisting of imidazolyl, benzimidazolyl, pyrazolyl, pyrazolinyl, pyrazolidinyl, oxadiazolyl, thiadiazolyl, pyridazinyl, pyrimidinyl, piperazinyl, purinyl, cinnolinyl, quinoxalinyl, and phenanthrenyl groups.

3. The OLED according to claim 1, wherein the organic metal complex including beryllium is BeBq₂.

4. The OLED according to claim 1, wherein the organic metal complex including beryllium is present in the electron transport layer at a concentration of 10 to 60 wt %.

5. The OLED according to claim 1, wherein the organic layer does not include a separate electron injection layer.

6. An organic light emitting diode (OLED), comprising:
a first electrode;
an organic layer disposed on the first electrode, and including an emission layer and an electron transport layer; and
a second electrode disposed on the organic layer,
wherein the electron transport layer includes an organic metal complex including beryllium and a compound of formula 1: 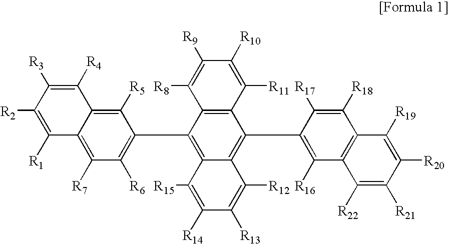
wherein, R₁ to R₇ and R₁₆ to R₂₂ are independently selected from the group consisting of hydrogen, phenyl, indenyl, naphthalenyl, benzofuranyl, benzothiophenyl, indolyl, benzimidazolyl, benzothiazolyl, purinyl, quinolinyl, isoquinolinyl, coumarinyl, cinnolinyl, quinoxalinyl, azulenyl, fluorenyl, dibenzofuranyl, carbazolyl, anthracenyl, phenanthrenyl, aziridinyl, 1,10-phenanthrolinyl, phenothiazinyl and pyrenyl groups, and
one of R₈ to R₁₅ is a phenyl group that is coupled with a C3-C30 aromatic heterocyclic group having one ring that includes two nitrogen atoms, and the other ones of R₈ to R₁₅ are independently selected from the group consisting of hydrogen, phenyl, indenyl, naphthalenyl, benzofuranyl, benzothiophenyl, indolyl, benzothiazolyl, quinolinyl, isoquinolinyl, coumarinyl, azulenyl, fluorenyl, dibenzofuranyl, carbazolyl, anthracenyl, phenanthrenyl, aziridinyl, phenothiazinyl, and pyrenyl groups.

7. The OLED according to claim 6, wherein the C3 to C30 aromatic heterocyclic group having one ring that includes two nitrogen atoms is one selected from the group consisting of imidazolyl, benzimidazolyl, pyrazolyl, pyrazolinyl, pyrazolidinyl, oxadiazolyl, thiadiazolyl, pyridazinyl, pyrimidinyl, piperazinyl, purinyl, cinnolinyl, quinoxalinyl, and phenanthrenyl groups.

8. The OLED according to claim 6, wherein the organic metal complex including beryllium is BeBq₂.

9. The OLED according to claim 6, wherein the organic metal complex including beryllium is present in the electron transport layer at a concentration of 10 to 60 wt %.

10. The OLED according to claim 1, wherein the organic layer does not include a separate electron injection layer.

11. A method of fabricating an organic light emitting diode (OLED), comprising:
preparing a first electrode;
forming an organic layer including an emission layer and an electron transport layer on the first electrode; and
forming a second electrode on the organic layer,
wherein the electron transport layer is formed by co-depositing an organic metal complex having beryllium and a compound of Formula 1: 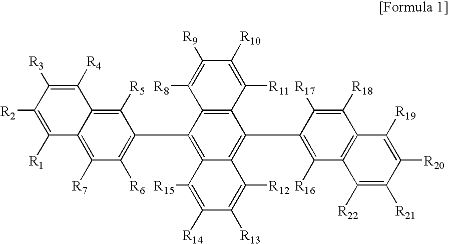
wherein, R₁ to R₇, and R₁₆ to R₂₂ are independently selected from the group consisting of hydrogen, phenyl, indenyl, naphthalenyl, benzofuranyl, benzothiophenyl, indolyl, benzimidazolyl, benzothiazolyl, purinyl, quinolinyl, isoquinolinyl, coumarinyl, cinnolinyl, quinoxalinyl, azulenyl, fluorenyl, dibenzofuranyl, carbazolyl, anthracenyl, phenanthrenyl, aziridinyl, 1,10-phenanthrolinyl, phenothiazinyl and pyrenyl groups, and
at least one of R₈ to R₁₅ is a C3-C30 aromatic heterocyclic group having one ring that includes two nitrogen atoms, and the other ones of R₈ to R₁₅ are independently selected from the group consisting of hydrogen, phenyl, indenyl, naphthalenyl, benzofuranyl, benzothiophenyl, indolyl, benzothiazolyl, quinolinyl, isoquinolinyl, coumarinyl, azulenyl, fluorenyl, dibenzofuranyl, carbazolyl, anthracenyl, phenanthrenyl, aziridinyl, phenothiazinyl, and pyrenyl groups, with the proviso that a compound in which R₁ to R₈, R₁₁ and R₁₂, and R₁₅ to R₂₂ include hydrogen, and one of R₉, R₁₀, R₁₃ and R₁₄ is the C3 to C30 aromatic heterocyclic group having one ring that includes two nitrogen atoms is specifically excluded.

12. The method according to claim 11, wherein the C3 to C30 aromatic heterocyclic group having one ring that includes two nitrogen atoms is one selected from the group consisting of imidazolyl, benzimidazolyl, pyrazolyl, pyrazolinyl, pyrazolidinyl, oxadiazolyl, thiadiazolyl, pyridazinyl, pyrimidinyl, piperazinyl, purinyl, cinnolinyl, quinoxalinyl, and phenanthrenyl groups.

13. The method according to claim 11, wherein the organic metal complex including beryllium is BeBq₂.

14. The method according to claim 11, wherein the organic layer is formed such that the organic metal complex including beryllium is present in the electron transport layer at a concentration of 10 to 60 wt %.

15. A method of fabricating an organic light emitting diode, comprising:
preparing a first electrode;
forming an organic layer including an emission layer and an electron transport layer on the first electrode; and
forming a second electrode on the organic layer,
wherein the electron transport layer is formed by co-depositing an organic metal complex including beryllium and a compound of Formula 1: 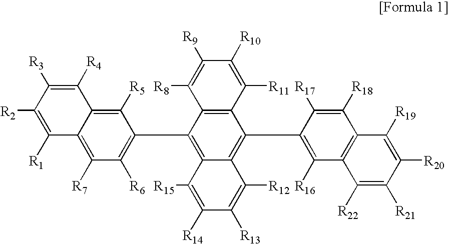
wherein, R₁ to R₇, and R₁₆ to R₂₂ are independently selected from the group consisting of hydrogen, phenyl, indenyl, naphthalenyl, benzofuranyl, benzothiophenyl, indolyl, benzimidazolyl, benzothiazolyl, purinyl, quinolinyl, isoquinolinyl, coumarinyl, cinnolinyl, quinoxalinyl, azulenyl, fluorenyl, dibenzofuranyl, carbazolyl, anthracenyl, phenanthrenyl, aziridinyl, 1,10-phenanthrolinyl, phenothiazinyl and pyrenyl groups, and
one of R₈ to R₁₅ is a phenyl group that is coupled with a C3-C30 aromatic heterocyclic group having one ring that includes two nitrogen atoms, and the other ones of R₈ to R₁₅ are independently selected from the group consisting of hydrogen, phenyl, indenyl, naphthalenyl, benzofuranyl, benzothiophenyl, indolyl, benzothiazolyl, quinolinyl, isoquinolinyl, coumarinyl, azulenyl, fluorenyl, dibenzofuranyl, carbazolyl, anthracenyl, phenanthrenyl, aziridinyl, phenothiazinyl, and pyrenyl groups.

16. The method according to claim 15, wherein the C3 to C30 aromatic heterocyclic group having one ring that includes two nitrogen atoms is one selected from the group consisting of imidazolyl, benzimidazolyl, pyrazolyl, pyrazolinyl, pyrazolidinyl, oxadiazolyl, thiadiazolyl, pyridazinyl, pyrimidinyl, piperazinyl, purinyl, cinnolinyl, quinoxalinyl, and phenanthrenyl groups.

17. The method according to claim 15, wherein the organic metal complex including beryllium is BeBq₂.

18. The method according to claim 15, wherein the organic layer is formed such that the organic metal complex including beryllium is present in the electron transport layer at a concentration of 10 to 60 wt %.
